(19) United States
(12) Patent Application Publication
(10) Pub. No.: US 2026/0182087 A1
(43) Pub. Date: Jun. 25, 2026

(54) METHOD FOR MANUFACTURING A SEMICONDUCTOR DEVICE AND SEMICONDUCTOR DEVICE

(71) Applicant: ams-OSRAM International GmbH, Regensburg (DE)

(72) Inventor: Adrian Avramescu, Regensburg (DE)

(21) Appl. No.: 19/126,158

(22) PCT Filed: Oct. 30, 2023
(86) PCT No.: PCT/EP2023/080222

§ 371 Date: Apr. 30, 2025

(30) Foreign Application Priority Data
Nov. 3, 2022 (DE) 10 2022 129 073.5

(51) Int. Cl. H10H 20/01; H10D 30/66; H10D 62/832; H10D 62/85; H10H 20/812; H10H 20/824; H10H 20/857; H10P 14/20

(52) U.S. Cl. CPC H10H 20/018; H10D 30/66; H10D 62/8325; H10D 62/8503; H10H 20/812; H10H 20/824; H10H 20/857; H10P 14/3216; H10P 14/3416

(57) ABSTRACT

In an embodiment a method for manufacturing a semiconductor device includes forming a compound semiconductor layer over a growth substrate, the compound semiconductor layer including N, an element E selected from the group consisting of Sc, Y, Nb, and Ta, and at least one group III element selected from the group consisting of Al, In and Ga, after forming, annealing the compound semiconductor layer at a temperature larger than 1000° and less than 1200° C., and after annealing, epitaxially forming a semiconductor body including an InₓAl_{y}Ga_{1-x-y}N layer over the compound semiconductor layer, wherein 0≤x≤1, 0≤y≤1.

### CROSS-REFERENCE TO RELATED APPLICATIONS

This patent application is a national phase filing under section 371 of PCT/EP2023/080222, filed Oct. 30, 2023, which claims the priority of German patent application no. 10 2022 129 073.5, filed Nov. 3, 2022, each of which is incorporated herein by reference in its entirety.

### TECHNICAL FIELD

Due to their large bandgap, GaN- or InGaN-based semiconductor materials are increasingly employed in a variety of applications. There is a need to provide improved methods for manufacturing GaN- or InGaN-based semiconductor devices.

### SUMMARY

Embodiments provide an improved method for manufacturing a semiconductor device and an improved semiconductor device.

A method for manufacturing a semiconductor device comprises forming a compound semiconductor layer over a growth substrate. The compound semiconductor layer comprises N, a further element E selected from Sc, Y, Nb, and Ta, and at least one group III element selected from Al, In and Ga. The method further comprises epitaxially forming a semiconductor body including an InₓAl_{y}Ga_{1-x-y}N layer over the compound semiconductor layer, wherein 0≤x≤1, 0≤y≤1.

According to embodiments, the method may further comprise an annealing process after forming the compound semiconductor layer and before epitaxially forming the semiconductor body. Optionally, the annealing process may be performed at a temperature larger than 1000° C. and less than 1200° C.

For example, the method may further comprise forming a cap layer comprising a nitride compound over the compound semiconductor layer before performing the annealing process. For example, the cap layer may comprise GaN.

For example, the growth substrate may be selected from sapphire and silicon.

According to embodiments, the semiconductor body comprises a first semiconductor layer of a first conductivity type on a side facing the compound semiconductor layer, a second semiconductor layer of a second conductivity type and an active zone between the first and the second semiconductor layers, the first semiconductor layer, the active zone and the second semiconductor layer forming a semiconductor layer stack.

By way of example, a layer thickness of the first semiconductor layer may be less than 3 μm. For example, the first semiconductor layer may comprise one or more layers of the first conductivity type. According to a different interpretation, the distance between the compound semiconductor and the active zone may be less than 3 μm.

The method may further comprise attaching a carrier over the second semiconductor layer.

According to embodiments, the method may further comprise at least partially removing the growth substrate.

The method may further comprise setting a content of E in the compound semiconductor layer in dependence from a bandgap of a material of the semiconductor body adjacent to the compound semiconductor layer.

According to further embodiments, the method may further comprise setting a content of E in the compound semiconductor layer in dependence of the group III elements constituting the compound semiconductor layer.

According to embodiments, an optoelectronic semiconductor device comprises an n-type Inₓ₁Al_{y1}Ga_{1-x1-y1}N layer, a p-type Inₓ₂Al_{y2}Ga_{1-x2-y2}N layer and an active zone for generating or absorbing electromagnetic radiation between the n-type and the p-type layers, wherein 0≤x1, x2≤1, 0≤y1, y2≤1. A thickness of the n-type layer is less than 3 μm.

For example, the n-type layer may further include at least one of Sc, Hf, Y, Ta, and Nb.

According to further embodiments, a semiconductor device comprises a compound semiconductor layer, the compound semiconductor layer comprising N, a further element E, wherein E is selected from Sc, Y, Nb, and Ta, and at least one group III element selected from Al, In and Ga. The semiconductor device further comprises an epitaxially grown semiconductor body including an InₓAl_{y}Ga_{1-x-y}N layer directly adjacent to the compound semiconductor layer, wherein 0≤x≤1, 0≤y≤1.

According to embodiments, the compound semiconductor layer may be arranged over a growth substrate being selected from sapphire and silicon.

For example, the semiconductor body comprises a first semiconductor layer of a first conductivity type on a side facing the compound semiconductor layer, a second semiconductor layer of a second conductivity type and an active zone between the first and the second semiconductor layers, the first semiconductor layer, the active zone and the second semiconductor layer forming a semiconductor layer stack.

### BRIEF DESCRIPTION OF THE DRAWINGS

The accompanying drawings are included to provide a further understanding of embodiments of the invention and are incorporated in and constitute a part of this specification. The drawings illustrate the embodiments of the present invention and together with the description serve to explain the principles. Other embodiments of the invention and many of the intended advantages will be readily appreciated, as they become better understood by reference to the following detailed description. The elements of the drawings are not necessarily to scale relative to each other. Like reference numbers designate corresponding similar parts.

FIG. 1A shows a workpiece when performing a method according to embodiments;

FIG. 1B shows a workpiece after performing a further processing step;

FIG. 1C shows a workpiece after performing further processing steps;

FIG. 2 summarizes a method according to embodiments;

FIG. 3A shows a cross-sectional view of a semiconductor device according to embodiments;

FIG. 3B shows a cross-sectional view of a semiconductor device according to further embodiments; and

FIG. 3C shows a cross-sectional view of a semiconductor device according to further embodiments.

### DETAILED DESCRIPTION OF ILLUSTRATIVE EMBODIMENTS

In the following detailed description reference is made to the accompanying drawings, which form a part hereof and in which are illustrated by way of illustration specific embodiments in which the invention may be practiced. In this regard, directional terminology such as “top”, “bottom”, “front”, “back”, “over”, “on”, “above”, “leading”, “trailing” etc. is used with reference to the orientation of the Figures being described. Since components of embodiments of the invention can be positioned in a number of different orientations, the directional terminology is used for purposes of illustration and is in no way limiting. It is to be understood that other embodiments may be utilized and structural or logical changes may be made without departing from the scope defined by the claims.

The description of the embodiments is not limiting. In particular, elements of the embodiments described hereinafter may be combined with elements of different embodiments.

The terms “wafer” or “semiconductor substrate” used in the following description may include any semiconductor-based structure that has a semiconductor surface. Wafer and structure are to be understood to include doped and undoped semiconductors, epitaxial semiconductor layers, e.g. supported by a base semiconductor foundation, and other semiconductor structures. This specification particularly refers to nitride-compound semiconductors, by which e.g. ultraviolet or blue light or longer wavelength light may be generated, such as GaN, InGaN, AlN, AlGaN, AlGaInN. The stoichiometric ratio of the compound semiconductor materials may vary.

The term “substrate” generally encompasses insulating, conductive or semiconductor substrates.

The term “vertical” as used in this specification intends to describe an orientation which is arranged perpendicular to the first surface of a substrate or semiconductor body.

The terms “lateral” and “horizontal” as used in this specification intends to describe an orientation parallel to a first surface of a substrate or semiconductor body. This can be for instance the surface of a wafer or a die.

For the epitaxial growth of nitride semiconductors such as GaN or InGaN semiconductors, a low-cost GaN substrate is not readily available. For example, sapphire or silicon substrates may be taken as growth substrates. These substrates have a coefficient of thermal expansion (CTE) and a lattice parameter which are different from the CTE and the lattice parameter of GaN or InGaN. Accordingly, there is a risk of higher wafer bow and/or high defect density of the nitride semiconductor layers which are grown on these substrates. Accordingly, problems with yield and performance may occur. Additionally, due to these issues, mass production using large diameter substrates may be difficult to be implemented.

As will be explained in the following, these problems may be overcome by using an improved method for manufacturing a semiconductor device.

According to embodiments, a method for manufacturing a semiconductor device comprises forming a compound semiconductor layer over a growth substrate. The compound semiconductor layer comprises N, a further element E and at least one group III element selected from Al, In and Ga. The further element E may be selected so that the atomic radius, more specifically the covalent radius for a single bond to Nitrogen is larger than the covalent radius of Ga in GaN. For example, the covalent radius of Ga in GaN may be approximately 124 pm. The covalent radius of Sc (e.g. 148 μm), Y (e.g. 163 μm), Hf (e.g. 152 μm), Zr (e.g. 154 μm), Nb (e.g. 147 μm), and Ta (e.g. 146 μm) in a nitride compound is larger than the covalent radius of Ga in GaN. Accordingly, E may be selected from any of these materials. For example, E may be Sc, Y, Nb or Ta. For example, the compound semiconductor layer may be epitaxially formed.

Thereafter, a semiconductor body including an InₓAl_{y}Ga_{1-x-y}N layer is epitaxially grown over the compound semiconductor layer, wherein 0≤x≤1, 0≤y≤1. For example, the InₓAl_{y}Ga_{1-x-y}N layer may be grown to be in contact with and directly adjacent to the compound semiconductor layer.

As has been mentioned above, problems associated with epitaxial growth of nitride semiconductors are based on a difference between lattice parameters of the growth substrate and the nitride semiconductor layer. Accordingly, by choosing an element E which has a larger covalent radius for a single bond to Nitrogen than gallium, as a constituent of the semiconductor compound layer, a crystal having a larger size is achieved. As a consequence, the lattice parameter of the compound semiconductor layer is larger than the lattice parameter of the GaN layer. By forming a compound semiconductor layer having a larger lattice parameter between the nitride semiconductor layer, a lattice mismatch may be reduced between the nitride semiconductor layer and the growth substrate.

Moreover, a covalent radius of element E for a single bond to Nitrogen is larger than the covalent radius of Ga e.g. in GaN. Due to the larger covalent radius of the E in a nitride, the E-nitride layer is more stable than a GaN or InN layer. Hence, it is possible to apply a higher temperature and perform an annealing step at temperatures larger than approximately 1000° C. Examples of element E may be Sc, Y, Nb, TaHf.

For example, the compound semiconductor layer may be an Al₁₋ₓScₓN layer. According to examples, x may be in a range of 0.16 to 0.26. Such a compound semiconductor layer is for example suitable for a GaN or an InGaN layer to be subsequently formed.

According to further examples, the compound semiconductor layer may be a Ga₁₋ₓScₓN layer. According to examples, x may be in a range from 0.02 to 0.16. Such a compound semiconductor layer is for example suitable for a GaN or an InGaN layer to be subsequently formed.

By adjusting the concentration of element E, a lattice parameter of the compound semiconductor layer may be adjusted. For example, the lattice parameter or lattice constant of the compound semiconductor layer may be adjusted to be in a range of the InₓAl_{y}Ga_{1-x-y}N layer to be grown subsequently. Accordingly, the content of element E may be selected in dependence from a composition ratio of the InₓAl_{y}Ga_{1-x-y}N layer of a material of the semiconductor body adjacent to the compound semiconductor layer. Since the lattice parameter depends on the bandgap which in turn depends on the composition ratio, the content of E may depend from the bandgap of the material of the semiconductor body. Further, the content of E may depend on the specific choice of the group III element which is further present in the compound semiconductor layer.

Due to the method described above, defects in the semiconductor body may be reduced, resulting in improved device characteristics.

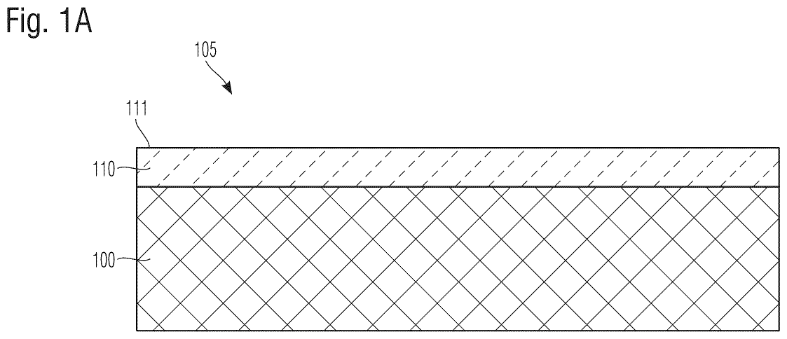

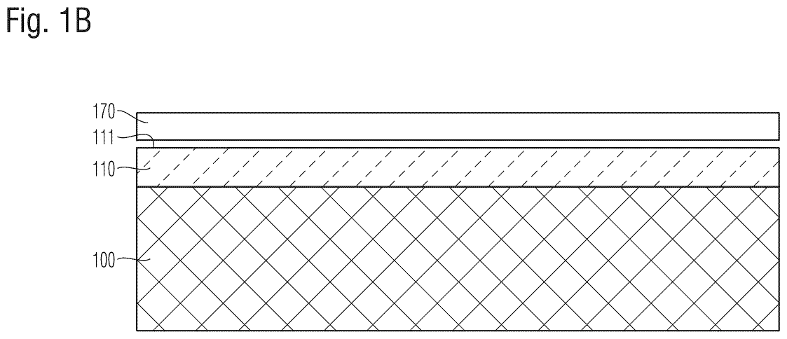

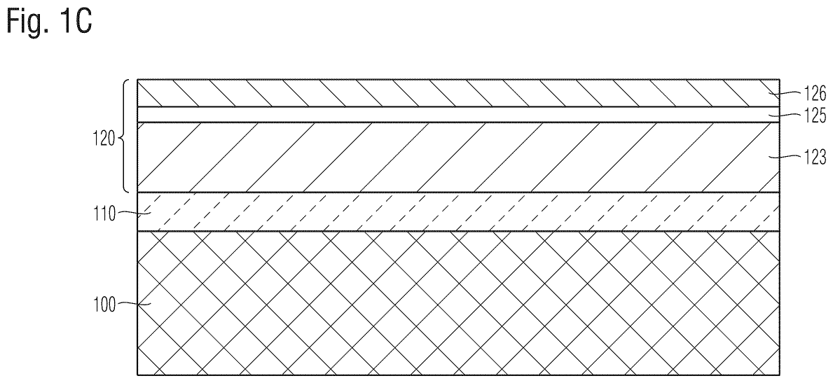

In the following, the method will be explained in more detail while referring to FIGS. 1A to 1C. A compound semiconductor layer 110 as has been explained above, is formed over a growth substrate 100. For example, the growth substrate may be selected from sapphire and silicon or other materials. The compound semiconductor layer 110 may be formed as an epitaxial layer e.g. using a sputtering, MBE (“molecular beam epitaxy”), MOCVD (“metal-organic chemical vapor deposition”) or ALD (“atomic layer deposition”) method. For example, the sputtering process may be epitaxial, e.g. it may be performed done at a high temperature or very low rate so that the deposited layer may be mostly ordered in relation/orientation to the substrate. For example, the compound semiconductor layer may have a thickness of more than approximately 5 nm or 40 nm. A thickness of the compound semiconductor layer may be less than 500 nm or less than approximately 300 nm. The thickness may be selected depending on the substrate material and the needed annealing temperature. For example, the thickness may be determined so that the lowest density of defects after annealing is obtainable. For example, during this method, a residual oxygen content in the atmosphere is precisely controlled for stabilization of the hexagonal crystal structure and the adjustment of the lattice parameter.

FIG. 1A shows an example of a resulting workpiece 105. FIG. 1A shows a strain relief substrate which comprises a usually employed growth substrate 100 and the compound semiconductor layer 110 as has been discussed above. For example, the compound semiconductor layer 110 may be selected from AlScN, AlHfN, AlYN, GaScN, GaHfN, GaYN, AlInScN, AlInHfN, AlInYN. For example, an In content of AlInScN, AlInHfN or AlInYN may be less than 5%.

Thereafter, an annealing process may be performed. For example, this annealing process may be performed at high temperatures e.g. larger than 1100° C. in an N2 atmosphere. This annealing process is performed for defect reduction. This annealing process may be performed under a locally controlled partial pressure of the components of the compound semiconductor layer 110.

As is indicated in FIG. 1B, a cap layer 170 may be arranged over the first main surface 111 of the compound semiconductor layer 110 during this annealing process. For example, the cap layer may be a nitride-based layer or cover. The cap layer 170 may, for example, be a GaN layer or include a GaN layer. Due to the presence of the cap layer 170, the local partial pressure is increased during the annealing step.

According to further examples, an additional workpiece 105 as illustrated in FIG. 1A may be arranged over the first main surface 111 of the compound semiconductor layer 110, so that the first main surfaces 111 face each other. According to further examples, during the annealing step the cap layer 170 may be dispensed with. In this case, the N2 pressure may be increased. Further, the group III element may be present at a higher concentration.

Thereafter, the semiconductor body 120 is epitaxially formed over the compound semiconductor layer 110. For example, the semiconductor body 120 may be formed using an MOCVD or MBE or further method. As is illustrated in FIG. 1C, the semiconductor body 120 may, for example, comprise a first semiconductor layer 123 of a first conductivity type, e.g. n-type, and a second semiconductor layer 126 of a second conductivity type, e.g. p-type. The first and the second semiconductor layers 123, 126 may have a composition of InₓAl_{y}Ga_{1-x-y}N, wherein 0≤x≤1, 0≤y≤1. The first and the second semiconductor layers may have a different composition or an identical composition. An active zone 125 may be arranged between the first and the second semiconductor layers 123, 126.

The active zone 125 may, for example, comprise a pn junction, a double heterostructure, a single quantum well (SQW) structure or a multi quantum well (MQW) structure for generating radiation. In this regard, the term “quantum well structure” has no meaning with regard to the dimensionality of the quantization. Thus, it includes, among other things, quantum wells, quantum wires and quantum dots, as well as any combination of these layers.

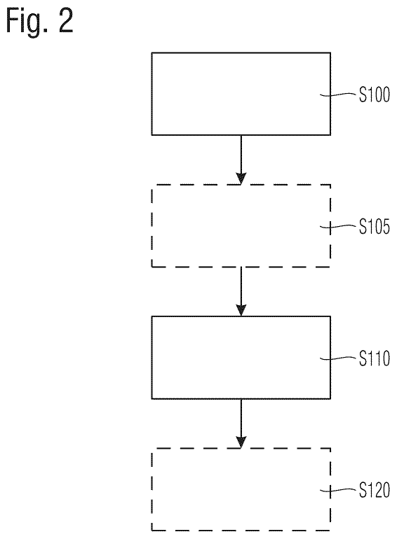

FIG. 2 summarizes a method according to embodiments. A method for manufacturing a semiconductor device comprises forming (S100) a compound semiconductor layer over a growth substrate, the compound semiconductor layer comprising N, a further element E selected from Sc, Y, Nb, and Ta, and at least one group III element selected from Al, In and Ga. The method further comprises epitaxially forming (S110) a semiconductor body including an InₓAl_{y}Ga_{1-x-y}N layer over the compound semiconductor layer, wherein 0≤x≤1, 0≤y≤1.

Optionally, an annealing step (S 105) may be performed after forming the compound semiconductor layer. For example, due to this annealing step, defects may be further reduced. For example, the annealing step may be performed at temperatures larger than 1000° C. and less than 1200° C. The method may further comprise at least partially removing (S120) the growth substrate 100 from the semiconductor body. Due to this removing step, also the compound semiconductor layer 110 may be removed. According to further embodiments the compound semiconductor layer 110 may be maintained. According to still further embodiments, also the growth substrate 100 may be maintained.

Due to the method described, a lattice-matched growing condition may be achieved. Hence, it is possible to grow the semiconductor body at a reduced stress. As a consequence, a low defect density in the epitaxially grown semiconductor body 120 may be achieved. Further, substrates with a substantially larger diameter (up to 300 mm) may be employed, thereby the production efficiency may be increased.

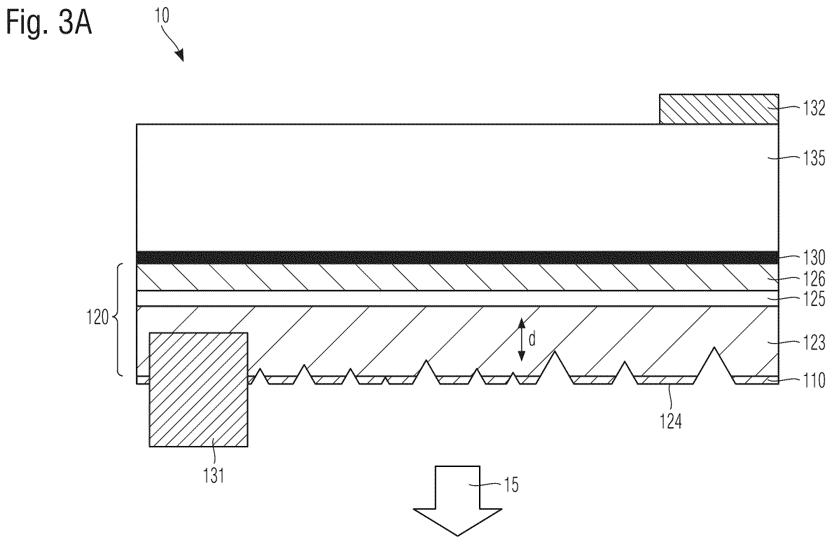

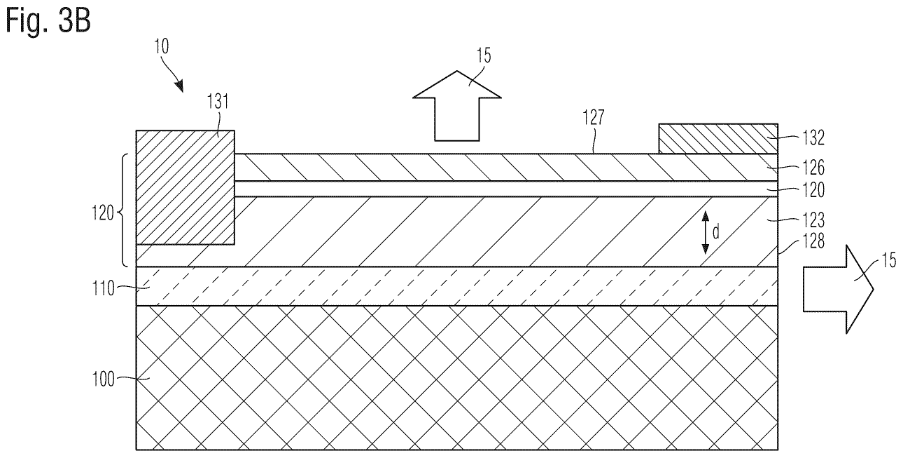

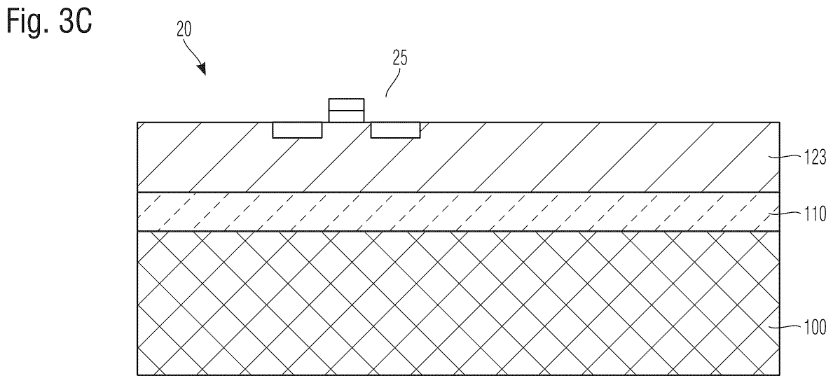

FIG. 3A shows an optoelectronic semiconductor device 10 according to embodiments. The optoelectronic semiconductor device 10 comprises a first semiconductor layer 123 of a first conductivity type, e.g. n-type. The first semiconductor layer 123 may have a composition of Inₓ₁Al_{y1}Ga_{1-x1-y1}N. The optoelectronic semiconductor device 10 further comprises a second semiconductor layer 126 of a second conductivity type, e.g. p-type. The second semiconductor layer 126 may have a composition ratio of Inₓ₂Al_{y2}Ga_{1-x2-y2}N. In the above formulas, 0≤x1, x2≤1, 0≤y1, y2≤1. An active zone 125 may be arranged between the first and the second semiconductor layers 123, 126. The active zone 125 may be configured to absorb or generate electromagnetic radiation. A first main surface 124 of the first semiconductor layer 123 may be roughened or corrugated. Electromagnetic radiation 15 generated within the active zone 125 may be emitted via the first main surface 124 of the first semiconductor layer 123. As is illustrated in FIG. 3A, residues of the compound semiconductor layer 110 may be arranged over the first main surface 124 of the first semiconductor layer 123. Still further, the element E may be present in the first semiconductor layer 123. For example, Sc, Ta, Nb, Hf or Y may be present at a small ratio within the first semiconductor layer 123. The thickness d of the first semiconductor layer 123 is less than 3 μm. Due to the use of the compound semiconductor layer 110, the first semiconductor layer 123 may be epitaxially grown at a lower defect density. As a result, even with a small thickness of the first semiconductor layer 123, the active zone 125 having a reduced density of defects may be epitaxially grown. For example, the thickness d of the first semiconductor layer 123 may be less than 1 μm or even less than 500 nm. According to embodiments, the first semiconductor layer 123 may comprise different semiconductor layers. According to an alternative interpretation, a distance between a first main surface 124 of the first semiconductor layer 110 and the active zone 125 may be less than 3 μm of less than 1 μm or even less than 500 nm.

Due to the reduced thickness of the first semiconductor layer 123, the optoelectronic semiconductor device may be implemented as a thin film semiconductor device. Moreover, due to the reduced thickness of the first semiconductor layer 123, cost of the device may be reduced.

A first contact element 131 may be arranged in electrical contact with the first semiconductor layer 123. The semiconductor body 120 may be mounted to a suitable carrier 135, e.g. by means of an adhesive or bonding layer. Moreover, a mirror layer 130 may be arranged between the second semiconductor layer 126 and the carrier 135. Due to the presence of the mirror layer 130, electromagnetic radiation is reflected towards the first main surface 124 of the first semiconductor layer 123. Due to the patterning of the first main surface 124 of the first semiconductor layer 123, reflections at the first main surface 124 may be reduced. As a consequence, the efficiency of the device is increased. FIG. 3A further shows a second contact element 132 electrically connected to the second semiconductor layer 126.

FIG. 3B shows a further example of an optoelectronic semiconductor device 10 which is similar to the optoelectronic semiconductor device illustrated in FIG. 3A. Differing from the optoelectronic semiconductor device 10 illustrated in FIG. 3A, electromagnetic radiation 15 is emitted via the first main surface 127 of the second semiconductor layer 126 or via a sidewall 128 of the semiconductor device. In this case, the growth substrate 100 and the compound semiconductor layer 110 may be maintained. Accordingly, the semiconductor device 10 shown in FIG. 3B comprises a compound semiconductor layer 110 over a growth substrate 100. The compound semiconductor layer 110 comprises N, a further element E selected from Sc, Y, Nb, and Ta and at least one group III element selected from Al, In and Ga. The semiconductor device 10 further comprises an epitaxially grown semiconductor body 120 including an InₓAl_{y}Ga_{1-x-y}N layer over the compound semiconductor layer 110, wherein 0≤x≤1, 0≤y≤1. The semiconductor body 120 may comprise a first semiconductor layer 123 of a first conductivity type, a second semiconductor layer 126 of a second conductivity type, and an active zone 125.

According to embodiments, the semiconductor body 120 may comprise one or more semiconductor layers. For example, as is illustrated in FIG. 3C, the semiconductor layer, e.g. a first semiconductor layer 123 of a first conductivity type, e.g. n-type, or of a second type, e.g. p-type, may be arranged over the compound semiconductor layer 110 as described above. For example, the semiconductor device 20 illustrated in FIG. 3C may be an arbitrary semiconductor device 20. For example, the semiconductor device 20 may be comprise arbitrary circuit elements 25 such as transistors, and others. The semiconductor device 20 may e.g. be a power semiconductor device.

While embodiments of the invention have been described above, it is obvious that further embodiments may be implemented. For example, further embodiments may comprise any subcombination of features recited in the claims or any subcombination of elements described in the examples given above. Accordingly, this spirit and scope of the appended claims should not be limited to the description of the embodiments contained herein.

1.-15. (canceled)

16. A method for manufacturing a semiconductor device, the method comprising:
forming a compound semiconductor layer over a growth substrate, the compound semiconductor layer comprising N, an element E selected from the group consisting of Sc, Y, Nb, and Ta, and at least one group III element selected from the group consisting of Al, In and Ga;
after forming, annealing the compound semiconductor layer at a temperature larger than 1000° and less than 1200° C.; and
after annealing, epitaxially forming a semiconductor body including an InₓAl_{y}Ga_{1-x-y}N layer over the compound semiconductor layer, wherein 0≤x≤1, 0≤y≤1.

17. The method according to claim 16, further comprising forming a cap layer comprising a nitride compound over the compound semiconductor layer before annealing the compound semiconductor layer.

18. The method according to claim 17, wherein the cap layer comprises GaN.

19. The method according to claim 16, wherein the growth substrate is selected from the group consisting of sapphire and silicon.

20. The method according to claim 16, wherein the semiconductor body comprises a first semiconductor layer of a first conductivity type on a side facing the compound semiconductor layer, a second semiconductor layer of a second conductivity type and an active zone for generating or absorbing electromagnetic radiation between the first and second semiconductor layers, and wherein the first semiconductor layer, the active zone and the second semiconductor layer form a semiconductor layer stack.

21. The method according to claim 20, wherein a layer thickness of the first semiconductor layer is less than 3 μm.

22. The method according to claim 20, further comprising attaching a carrier over the second semiconductor layer.

23. The method according to claim 22, further comprising at least partially removing the growth substrate.

24. The method according to claim 16, further comprising setting a content of E in the compound semiconductor layer in dependence from a bandgap of a material of the semiconductor body adjacent to the compound semiconductor layer.

25. The method according to claim 16, further comprising setting a content of E in the compound semiconductor layer in dependence of the group III elements constituting the compound semiconductor layer.

26. An optoelectronic semiconductor device comprising:
an n-type Inₓ₁Al_{y1}Ga_{1-x1-y1}N layer;
a p-type Inₓ₂Al_{y2}Ga_{1-x2-y2}N layer; and
an active zone configured for generating or absorbing electromagnetic radiation between the n-type layer and the p-type layer,
wherein 0≤x1, x2≤1, 0≤y1, y2≤1, and
wherein a thickness of the n-type layer is less than 3 μm.

27. The optoelectronic semiconductor device according to claim 26, wherein the n-type layer further includes at least one of Sc, Hf, Y, Zr, Nb, or Ta.

28. A semiconductor device comprising:
a compound semiconductor layer comprising N, an element E selected from the group consisting of Sc, Y, Nb, and Ta, and at least one group III element selected from the group consisting of Al, In and Ga; and
an epitaxially grown semiconductor body including an InₓAl_{y}Ga_{1-x-y}N layer directly adjacent to the compound semiconductor layer,
wherein 0≤x≤1, 0≤y≤1.

29. The semiconductor device according to claim 28, wherein the compound semiconductor layer is arranged over a growth substrate being selected from the group consisting of sapphire and silicon.

30. The semiconductor device according to claim 28, wherein the semiconductor body comprises a first semiconductor layer of a first conductivity type on a side facing the compound semiconductor layer, a second semiconductor layer of a second conductivity type and an active zone configured for generating or absorbing electromagnetic radiation between the first and the second semiconductor layers, wherein the first semiconductor layer, the active zone and the second semiconductor layer form a semiconductor layer stack.
